(19) United States
(12) Patent Application Publication
(10) Pub. No.: US 2016/0255718 A1
(43) Pub. Date: Sep. 1, 2016

(54) AN EPOXY RESIN COMPOSITION, AND PREPREG AND COPPER-CLAD LAMINATE MADE BY USING SAME

(71) Applicants: Yujun XIN, Guangdong (CN); Yong CHEN, Guangdong (CN); Xianping ZENG, Guangdong (CN); Yongjing XU, Guangdong (CN)

(72) Inventors: Yujun XIN, Guangdong (CN); Yong CHEN, Guangdong (CN); Xianping ZENG, Guangdong (CN); Yongjing XU, Guangdong (CN)

(21) Appl. No.: 14/407,632

(22) PCT Filed: Aug. 13, 2014
(86) PCT No.: PCT/CN2014/084303

§ 371 Date: Dec. 12, 2014

(30) Foreign Application Priority Data
Aug. 5, 2014 (CN) 201410381589.7

(51) Int. Cl. H05K 1/03; C08G 59/08; C08J 5/24; B32B 27/12; B32B 15/092; B32B 15/14; B32B 15/20; B32B 27/08; C08L 63/04; B32B 5/02

(52) U.S. Cl. CPC H05K 1/0373; C08L 63/04; C08G 59/08; C08J 5/24; B32B 5/02; B32B 15/092; B32B 15/14; B32B 15/20; B32B 27/08; B32B 27/12; H05K 1/0306; C08J 2363/04; B32B 2260/021; B32B 2260/046; B32B 2262/101; B32B 2307/204; B32B 2457/04

(57) ABSTRACT

The present invention related to an resin compound, especially to an epoxy resin composition and a prepreg and a copper-clad laminate made by using same. The epoxy resin composition of the present invention employs ester compound and flexible amine hardener to cure the epoxy resin, and the resin composition possesses excellent dielectric properties as well as high glass transition temperature and good toughness. The epoxy resin composition of the present invention, which applied in a prepreg and a copper-clad laminate, possesses excellent dielectric properties, high glass transition temperature and good impact toughness.

### TECHNICAL FIELD

The present invention relates to the field of resin composition, especially to an epoxy resin composition, and a prepreg and a laminate made by using same.

### BACKGROUND ART

In recent years, with the high-performance and multi-functionalization in computer and information communication equipment and development of network, the amount of data to be processed increases, and the speed of signal propagation is growing faster, thus it requires the circuit board used with a low dielectric constant and a low dielectric loss tangent, as well as keeping stable under a wide temperature and frequency. Meanwhile, electronic products are developed to be light, thin, short and small, the density and integration of the components assembly on the printed circuit board is becoming higher, it turned out to be smaller line layer spacing and narrower linewidth. So new demands of the process for circuit board of drilling, punching, edge milling and other processes have been put forward, the circuit board substrate should be good toughness and processability.

Conventional FR-4 laminate materials generally employ dicyandiamide as a hardener, the hygroscopicity of laminate materials is high, and the pyrolysis temperature is low, which is unable to meet the heat resistance requirement of lead-free process. Along with the large-scale implementation of the lead-free process after 2006, phenolic resins were started to be used as epoxy resin hardeners in the industry, such as, patent CN1966572A discloses an epoxy resin composition cured by phenolic resins, the composition has a high Tg and excellent heat resistance, but high brittleness, lack of toughness and poor PCB processability. Patent CN102304271A has disclosed that employing poly-1,4-butanediol bis (4-aminobenzoate) as toughener for epoxy resin composition in rigid-flexible combined board, which may obtain good flexibility, but the dielectric performance is general. Patent CN102443138A, CN102850722A have provided an epoxy resin composition, which employing epoxy resin containing dicyclopentadiene structure and naphthalene ring structure and using active esters as a hardener, the composition has a high glass transition temperature and excellent dielectric properties, but its toughness and processability are not mentioned.

### DISCLOSURE OF THE INVENTION

An object of the present invention lies in providing an epoxy resin composition, which has high glass transition temperature, good toughness and excellent dielectric performance.

Another object of the present invention lies in providing a prepreg and a laminate made by using the above mentioned epoxy resin composition, which have high glass transition temperature, good toughness and excellent dielectric performance.

In order to achieve these objects above, the present invention provides a thermosetting epoxy resin composition comprising components as follows: epoxy resin, flexible amine hardener and ester compound.

The flexible amine hardener is poly-1,4-butanediol bis(4-aminobenzoate) or poly (1,4-butanediol-3-methyl-1,4-butanediol)ether bis(4-aminobenzoate), wherein, the chemical structural formula of poly-1,4-butanediol bis(4-aminobenzoate) is as follow:

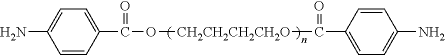

Wherein, the chemical structural formula of poly (1,4-butanediol-3-methyl-1,4-butanediol)ether bis(4-aminobenzoate) is as follow:

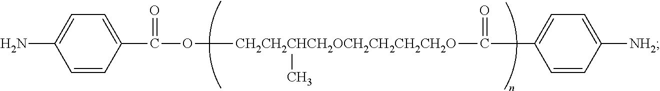

The active hydrogen equivalent of the flexible amine hardener should be controlled between 100 to 500 g/eq;
The amount of the flexible amine hardener, based on the ratio between amine hydrogen equivalent and epoxy resin epoxy equivalent, is 5˜30%. The amount of the ester compound, based on the ratio between ester equivalent and epoxy resin epoxy equivalent, is 70˜95%.

Preferably, the epoxy resin is the one that having two or more epoxy groups in one molecular epoxy resin, comprising at least one of these epoxy resin types, which are bisphenol A epoxy resins, bisphenol F epoxy resin, biphenyl epoxy resins, o-cresol epoxy resin, naphthol novolac epoxy resin, dicyclopentadiene epoxy resin.

Preferably, the ester compound is one or more ester compounds as follows:

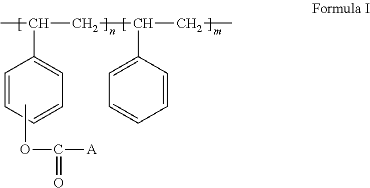

Wherein, A is a substituted or unsubstituted phenyl group, a substituted or unsubstituted naphthyl group, C1-C8 alkyl group, m and n is natural numbers, m/n=0.8-19;

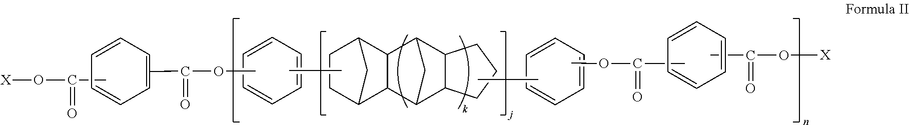

Wherein, X is benzene ring or naphthalene ring, j is 0 or 1, k is 0 or 1, and n represents that the average repeating unit is 0.25˜1.25.

Preferably, the thermosetting epoxy resin composition of the present invention also comprises a curing accelerator. The curing accelerator is one or a mixture of imidazole compounds and derivatives thereof, piperidine compounds, Lewis acids and triphenylphosphine.

Preferably, the thermosetting epoxy resin composition of the present invention also comprises a flame retardant. The amount of the flame retardant, relative to the epoxy resin, the flexible amine hardener and the ester compound, is 100 parts by weight total, preferred to be 5˜100 parts by weight. The flame retardant is bromine-containing or halogen-free. The bromine-containing flame retardant can be decabromodiphenyl ether, decabromodiphenyl ethane, brominated styrene, ethylene bis-tetrabromo phthalimide or brominated polycarbonate. The halogen-free flame retardant can be tris(2,6-dimethylphenyl)phosphine, 10-(2,5-dihydroxyphenyl)-9,10-dihydro-9-oxa-10-phosphaphenanthrene-10-oxide, 2,6-bis(2,6-dimethylphenyl)phosphine benzene, or 10-phenyl-9,10-dihydro-9-oxa-10-phosphaphenanthrene-10-oxide, phenoxyphosphazene cyanide compound, zinc borate, phosphate, polyphosphate, phosphorus-containing flame retardants, silicon-containing flame retardants, or nitrogen-containing flame retardants.

Preferably, the thermosetting epoxy resin composition of the present invention also comprises organic or inorganic filler. The mixed amount of the filler, relative to the total 100 parts by weight of the epoxy resin, the flexible amine hardener and the ester compound, is 5˜1000 parts by weight, preferred to be 5˜300 parts by weight. The inorganic filler is one or more selected from crystalline silica, fused silica, spherical silica, hollow silica, glass powder, aluminum nitride, boron nitride, silicon carbide, aluminum hydroxide, titanium dioxide, strontium titanate, barium titanate, aluminum oxide, barium sulfate, talcum powder, calcium silicate, calcium carbonate, and mica. The organic filler is one or more selected from polytetrafluoroethylene powder, polyphenylene sulfide, and polyether sulfone powder.

The present invention also provides a prepreg made by the epoxy resin composition above, comprising a reinforce material and the epoxy resin composition attached thereon after being impregnated and dried.

The present invention also provides a laminate made by the epoxy resin composition above, comprising at least one piece of prepreg mentioned above.

The beneficial effects of the present invention: (1) The epoxy resin composition of the present invention employs flexible amine hardener and ester compound together to cure the epoxy resin, and the resin composition possesses excellent dielectric properties as well as high glass transition temperature and good toughness. (2) The epoxy resin composition of the present invention was used in prepreg and copper-clad board, which makes the copper-clad board with excellent dielectric properties, high glass transition temperature and good impact toughness.

### EMBODIMENTS

The present invention provides an epoxy resin composition, comprising components as follows: epoxy resin, flexible amine hardener and ester compound.

The epoxy resin is the one that having two or more epoxy groups in one molecular epoxy resin, comprising at least one of these epoxy resin types, which are bisphenol A epoxy resins, bisphenol F epoxy resin, biphenyl epoxy resins, o-cresol epoxy resin, naphthol novolac epoxy resin, dicyclopentadiene type epoxy resin.

The flexible amine hardener is poly-1,4-butanediol bis(4-aminobenzoate) or poly (1,4-butanediol-3-methyl-1,4-butanediol)ether bis(4-aminobenzoate), wherein, the chemical structural formula of poly-1,4-butanediol bis(4-aminobenzoate) is as follow:

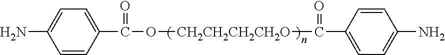

Wherein, the chemical structural formula of poly (1,4-butanediol-3-methyl-1,4-butanediol)ether bis(4-aminobenzoate) is as follow:

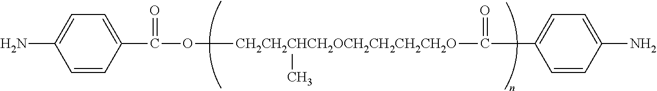

The active hydrogen equivalent of the flexible amine hardener should be controlled between 100-500 g/eq;

The amount of the flexible amine hardener, based on the ratio between amine hydrogen equivalent and epoxy resin epoxy equivalent, is 5˜30%, more preferred to be 5˜25%, and even more preferred to be 8˜20%. The amount of the ester compound, based on the content of epoxy resin and amine hardener, the equivalent ratio of 1:1, calculated by multiplying the amount coefficient, which is 0.7˜0.95.

The flexible amine hardener is a kind of P-amino benzoic acid derivatives, as the hardener, it has great flexibility, and the characteristic of decreasing the glass transition temperature of laminate materials slightly or none. The amino and carbonyl groups in the structure could form hydrogen bonds within their molecules or between other molecules, and the cohesion was improved. Therefore, the glass transition temperature of the original curing system could reduce less by adding it into the epoxy curing system, or maintain constant Tg.

The flexible amine hardener with the amount of less than 5%, is not obvious on improving the toughness of the cured product. The flexible amine hardener with the amount of more than 30%, can slow down the reaction of the cured product, while the reaction is incomplete, and affect the dielectric properties of the cured product.

The ester compound is one or more of the ester compounds as follows:

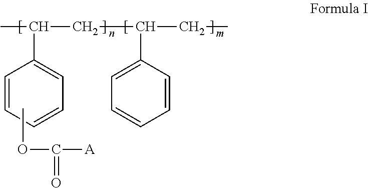

Wherein, A is a substituted or unsubstituted phenyl group, a substituted or unsubstituted naphthyl group, C1-C8 alkyl group, m and n is natural numbers, m/n=0.8-19. When m/n is greater than 19, the peel strength of the laminate material is too low that it causes dropped calls or other quality problems during PCB process. When m/n is less than 0.8, the dielectric properties of the laminate material may be deteriorated. In order to balance the dielectric constant, dielectric dissipation tangent, glass transition temperature, solder dipping resistance and peel strength, m/n is preferred to be 1-8.

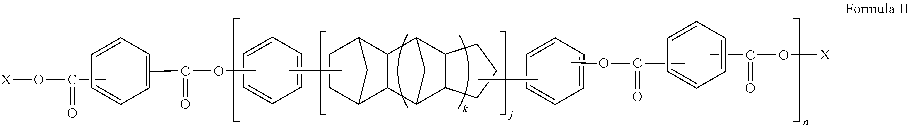

Wherein, X is benzene ring or naphthalene ring, j is 0 or 1, k is 0 or 1, and n represents that the average repeating unit is 0.25˜1.25.

The ester compound of formula II is obtained by reacting a phenolic compound linked by an aliphatic cyclic hydrocarbon structure, a bifunctional carboxylic acid aromatic compound or an acidic halide with a mono-hydroxyl compound.

The amount of the bifunctional carboxylic acid aromatic compound or the acidic halide is 1 mol. The amount of the phenolic compound linked by an aliphatic cyclic hydrocarbon structure is 0.05˜0.75 mol. The amount of the mono-hydroxyl compound is 0.25˜0.95 mol.

The ester compound of formula I is used to cure the epoxy resin, because there is a non-polar group on the molecular main chain, the polarity of the cured product is low, and thus the cured products have better dielectric performance and lower water absorption.

Preferably, the ester compound is the ester compound of formula I.

The epoxy resin of the present invention may also comprise a curing accelerator. Only if it can catalyze the reactions of epoxy functional groups and reduce the reaction temperature of curing system, no specific restriction is made to the curing accelerator and it is preferred to be one or more selected from imidazole compounds and derivatives thereof, piperidine compounds, Lewis acids and triphenylphosphine, or combinations thereof. The imidazole compounds may be exemplified as 2-methylimidazole, 2-phenylimidazole or 2-ethyl-4-methyl imidazole. The piperidine compounds may be exemplified as 2,3-diaminopiperidine, 2,5-diaminopiperidine, 2,6-diaminopiperidine, 2,5-diamino-3-methylpiperidine, 2-amino-4-4methylpiperidine, 2-amino-3-nitropiperidine, 2-amino-5-nitropiperidine, or 4-dimethylaminopiperidine. The amount of the curing accelerator, based on the total 100 parts by weight of the epoxy resin, the flexible amine hardener and the ester compound, is 0.05˜1.0 part by weight.

The present invention may also comprise flame retardant to provide the resin hardener with flame resistance properties, and reaches the requirements of UL94V-0. No specific restriction is made to the flame retardant added as needed, and it is preferred to have no effect on the dielectric properties, which may be a bromine-containing or a halogen-free flame retardant, a halogen flame retardant, a phosphorus-containing flame retardants, a silicon-containing flame retardant, a nitrogen-containing flame retardants, etc. The bromine-containing flame retardant can be decabromodiphenyl ether, decabromodiphenyl ethane, brominated styrene, ethylene bis-tetrabromo phthalimide or brominated polycarbonate. The halogen-free flame retardant can be tris(2,6-dimethylphenyl) phosphine, 10-(2,5-dihydroxyphenyl)-9,10-dihydro-9-oxa-10-phosphaphenanthrene-10-oxide, 2,6-bis(2,6-dimethylphenyl)phosphine benzene, or 10-phenyl-9,10-dihydro-9-oxa-10-phosphaphenanthrene-10-oxide, phenoxyphosphazene cyanide compound, zinc borate, phosphate, polyphosphate, phosphorus-containing flame retardants, silicon-containing flame retardants, or nitrogen-containing flame retardants. Commercialization products of brominated flame retardants which can be selected are BT-93, BT-93 W, HP-8010, HP-3010 manufactured by Albemarle corporation. The material of halogen-free flame retardant may be but not limited to SP-100, PX-200, PX-202, FR-700, OP-930, OP-935, XP-7866. The amount of flame retardant without specific limitation is determined according to the UL 94V-0 level of the curing product. The amount of the flame retardant, relative to the total 100 parts by weight of the epoxy resin, the flexible amine hardener and the ester compound, is preferred to be 5˜100 parts by weight, and more preferred to be 10˜50 parts by weight.

The present invention may also comprise organic and inorganic filler. No specific restriction is made to the filler added depending on the need. The inorganic filler can be one or more selected from crystalline silica, fused silica, spherical silica, hollow silica, glass powder, aluminum nitride, boron nitride, silicon carbide, aluminum hydroxide, titanium dioxide, strontium titanate, barium titanate, aluminum oxide, barium sulfate, talcum powder, calcium silicate, calcium carbonate and mica; the organic filler is one or more selected from polytetrafluoroethylene powder, polyphenylene sulfide and polyether sulfone powder. In addition, there is no restriction on the shape and particle size of the inorganic filler. In general the particle is 0.01-50 μm, preferred to be 0.01˜20 μm, and more preferred to be 0.1˜10 μm. Inorganic filler with such range of particle size is easier to disperse in resin solution. Further, there is no restriction on the mixed amount of the filler, which relative to the total 100 parts by weight of the epoxy resin, the flexible amine hardener and the ester compound, is 5-1000 parts by weight, preferred to be 5-300 parts by weight, more preferred to be 5-200 parts by weight, and even more preferred to be 5-150 parts by weight.

The prepreg made by using the epoxy resin composition above comprises a reinforce material and the epoxy resin composition attached thereon after being impregnated and dried. The reinforce material employs a reinforce material in the prior art like glass fiber cloth. The copper-clad laminate made by using the epoxy resin composition above comprises several laminated prepregs and copper foils covered on one or both sides of the laminated pregregs. The prepreg is made by the epoxy resin composition.

For the resulting copper-clad laminate above, the dielectric constant and dielectric dissipation factor, glass transition temperature, peel strength and interlayer adhesion are measured and further explained and described in detail in the following examples.

### Example 1

100 parts by weight of HP-7200HHH (dicyclopentadiene novolac epoxy resin, epoxy equivalent is 286 g/eq) was added, then 74.1 parts by weight of HPC-8000-65T (active ester compound, active ester equivalent is 223 g/eq) was added, and then 5.4 parts by weight of ELASMER-1000P (Poly-1,4-butanediol bis(4-aminobenzoate, active hydrogen equivalent is 309 g/eq) were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Example 2

100 parts by weight of HP-7200HHH (dicyclopentadiene novolac epoxy resin, epoxy equivalent is 286 g/eq) was added, then 70.2 parts by weight of HPC-8000-65T (active ester compound, active ester equivalent is 223 g/eq) was added, and then 10.8 parts by weight of ELASMER-1000P (Poly-1,4-butanediol bis (4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Example 3

100 parts by weight of HP-7200HHH (dicyclopentadiene novolac epoxy resin, epoxy equivalent is 286 g/eq) was added, then 54.6 parts by weight of HPC-8000-65T (active ester compound, active ester equivalent is 223 g/eq) was added, and then 32.4 parts by weight of ELASMER-1000P (Poly-1,4-butanediol bis(4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Example 4

100 parts by weight of HP-7200HHH (dicyclopentadiene novolac epoxy resin, epoxy equivalent is 286 g/eq) was added, then 104.8 parts by weight of eater compound 1 (active ester compound containing styrene structure, ShinA product SAP-820, m/n=8), and then 10.8 parts by weight of ELASMER-1000P (Poly-1,4-butanediol bis(4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Example 5

100 parts by weight of HP-7200HHH (dicyclopentadiene novolac epoxy resin, epoxy equivalent is 286 g/eq) was added, then 104.8 parts by weight of eater compound 2 (active ester compound containing styrene structure, ShinA product, m/n=1), and then 10.8 parts by weight of ELASMER-1000P (Poly-1,4-butanediol bis(4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Example 6

100 parts by weight of N-690 (o-cresol novolac epoxy resin, epoxy equivalent is 240 g/eq) was added, then 124.8 parts by weight of eater compound 1 (active ester compound containing styrene structure, ShinA product SAP-820, m/n=8), and then 12.9 parts by weight of ELASMER-1000P (Poly-1,4-butanediol bis(4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Example 7

100 parts by weight of N-7300 (naphthol type novolac epoxy resin, epoxy equivalent is 214 g/eq) was added, then 139.8 parts by weight of eater compound 1 (active ester compound containing styrene structure, ShinA product SAP-820, m/n=8), and then 14.4 parts by weight of ELASMER-1000P (Poly-1,4-butanediol bis(4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Comparative Example 1

100 parts by weight of HP-7200HHH (dicyclopentadiene novolac epoxy resin, epoxy equivalent is 286 g/eq) was added, then 77.9 parts by weight of HPC-8000-65T (active ester compound, active ester equivalent is 223 g/eq) was added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Comparative Example 2

100 parts by weight of HP-7200HHH (dicyclopentadiene novolac epoxy resin, epoxy equivalent is 286 g/eq) was added, then 69.9 parts by weight of eater compound 1 (active ester compound containing styrene structure, ShinA product SAP-820, m/n=8), and then 43.2 parts by weight of ELASMER-1000P (Poly-1,4-butanediol bis(4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Comparative Example 3

100 parts by weight of N-690 (o-cresol novolac epoxy resin, epoxy equivalent is 240 g/eq) was added, then 39.4 parts by weight of TD-2090 (linear novolac hardener, hydroxyl equivalent is 105 g/eq), and then 12.9 parts by weight of ELASMER-1000P (Poly-1,4-butanediol bis(4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

### Comparative Example 4

100 parts by weight of HP-7200HHH (Dicyclopentadiene phenolic epoxy resin, epoxy equivalent is 286 g/eq) was added, then 104.8 parts by weight of eater compound 3 (active ester compound, m/n=20) containing styrene structure (Poly-1,4-butanediol bis (4-aminobenzoate, active hydrogen equivalent is 309 g/eq), were added and stirred well. And then a proper amount of DMAP, which is curing accelerator, and solvent toluene were added, stirred uniformly to form a varnish, and the solid content of varnish was controlled to be 40-80%. The varnish above was impregnated with glass fiber cloth (model number 2116, the thickness is 0.08 mm) and controlled to a proper thickness, and then the solvent was evaporated to obtain a prepreg. Several resulting prepregs were laminated, on both sides of which a copper foil was respectively covered, placed into a hot press and cured to produce the copper-clad laminate. The data of physical properties are shown in table 1.

The source of reagents involved in the examples and comparative examples above are shown as follows:

HP-7200HHH is the dicyclopentadiene novolac epoxy resin manufactured by DIC.
N-690 is the o-cresol novolac epoxy resin manufactured by DIC.
NC-7300L is the naphthol novolac epoxy resin manufactured by Nippon Kayaku.
HPC-8000-65T is the active ester compound manufactured by DIC.
Ester compound 1 is the active ester compound manufactured by ShinA, and m/n=8.
Ester compound 2 is the active ester compound manufactured by ShinA, and m/n=1.
Ester compound 3 is the active ester compound manufactured by ShinA, and m/n=20.
ELASMER-1000P is flexible amine hardener manufactured by Ihara Chemical.
TD2090 is the phenol novolac resin manufactured by DIC.
DMAP is 4-dimethylaminopyridine.
2E4MZ is 2-ethyl-4-methylimidazole.

TABLE 1
physical property data of each example and comparative example

| Component | Example | Example | Example | Example | Example | Example |
|---|---|---|---|---|---|---|
| name | 1 | 2 | 3 | 4 | 5 | 6 |
| HP-7200HHH | 100 | 100 | 100 | 100 | 100 | |
| N-690 | | | | | | 100 |
| NC-7300L | | | | | | |
| HPC-8000-65T | 74.1 | 70.2 | 54.6 | | | |
| SAP-820 | | | | 104.8 | | 124.8 |
| Ester compound 1 | | | | | 104.8 | |
| Ester compound 2 | | | | | | |
| TD-2090 | | | | | | |
| ELASMER-1000P | 54 | 10.8 | 32.4 | 10.8 | 10.8 | 12.9 |
| DMAP | proper | proper | proper | proper | proper | proper |
| | amount | amount | amount | amount | amount | amount |
| 2E4MZ | | | | | | |
| Tg (DMA)/° C. | 180 | 175 | 170 | 185 | 180 | 190 |
| Dk/5G | 3.7 | 3.7 | 3.8 | 3.6 | 3.7 | 3.9 |
| Df/5G | 0.0085 | 0.0085 | 0.009 | 0.0075 | 0.008 | 0.010 |
| impact | ◯ | ⊚ | ⊚ | ⊚ | ⊚ | ◯ |
| toughness | | | | | | |
| | | | comparative | comparative | comparative | comparative |
| | Component | Example | example | example | example | example |
| | name | 7 | 1 | 2 | 3 | 4 |
| | HP-7200HHH | | 100 | 100 | | 100 |
| | N-690 | | | | 100 | |
| | NC-7300L | 100 | | | | |
| | HPC-8000-65T | | 77.9 | | | |
| | SAP-820 | 139.8 | | 69.9 | | |
| | Ester compound 1 | | | | | |
| | Ester compound 2 | | | | | 104.8 |
| | TD-2090 | | | | 39.4 | |
| | ELASMER-1000P | 14.4 | | 43.2 | 12.9 | 10.8 |
| | DMAP | proper | proper | proper | | proper |
| | | amount | amount | amount | | amount |
| | 2E4MZ | | | | proper | |
| | | | | | amount | |
| | Tg (DMA)/° C. | 180 | 183 | 165 | 205 | 160 |
| | Dk/5G | 3.7 | 3.7 | 4.2 | 4.5 | 4.2 |
| | Df/5G | 0.0075 | 0.0085 | 0.020 | 0.020 | 0.015 |
| | impact | ⊚ | Δ | Δ | X | Δ |
| | toughness | | | | | |

In table 1, “⊚” on behalf of “great”, “◯” on behalf of “good”, “Δ” on behalf of “average”, “X” on behalf of “bad”.

The properties above are measured by methods as follows.
(1) Glass transition temperature (Tg): measured with DMA test, according to the DMA test method as stipulated under IPC-TM-6502.4.24.
(2) Dielectric constant and dielectric dissipation factor: measured according to SPDR method.
(3) Evaluation of impact toughness: a laminate material of 50 mm*50 mm size was positioned in the center of the base, and then it was impact by a certain weight of solid hammer, which from a certain height with a certain speed. The width and length of the crack was observed and measured.

### Physical Property Analysis

It can be known from the physical property data in table 1, in the comparative examples 3, when using novolac epoxy resin and composite curing with linear phenolic resin and flexible amine hardener, the glass transition temperature is high, but the dielectric property is bad, and the impact resistance is bad. In the comparative examples 4, the composite curing was carried out by using ester compound 3 and flexible amine hardener as well as epoxy resin with dicyclopentadiene structure. Because the m/n in the ester compound 3 is 20, the curing reaction is slow and incomplete, the performance was general. In the comparative examples 1, when using epoxy resin contained dicyclopentadiene structure and curing with active ester hardener, the dielectric property is excellent and the impact resistance is general. In the comparative examples 2, when using epoxy resin contained dicyclopentadiene structure and curing with active ester compound and active amine hardener, and Poly-1,4-butanediol bis (4-aminobenzoate) is used in excess, a lot of amino is residual in the system, the hygroscopicity increased, the dielectric property is getting worse, and the impact toughness is general. In the examples 1-7, the epoxy resin was cured with an active ester compound, meanwhile a certain amount of flexible amine hardener was added to co-cured, the laminate material obtained possesses high glass transition temperature, excellent dielectric property and good impact toughness.

The examples above do not make any restriction on the contents of the composition of the present invention. Any slight alteration, equivalent change and modification according to the technical essence and the components or contents of the composition, all belong to the scope of the solution of the present invention.

1. An epoxy resin composition, comprising components as follows: epoxy resin, flexible amine hardener and ester compound;
the flexible amine hardener is poly-1,4-butanediol bis(4-aminobenzoate) or poly(1,4-butanediol-3-methyl-1,4-butanediol)ether bis(4-aminobenzoate) or combination thereof, wherein the chemical structural formula of poly-1, 4-butanediol bis(4-aminobenzoate) is as follows: 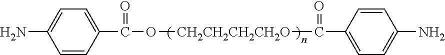
wherein the chemical structural formula of poly(1,4-butanediol-3-methyl-1,4-butanediol)ether bis(4-aminobenzoate) is as follows: 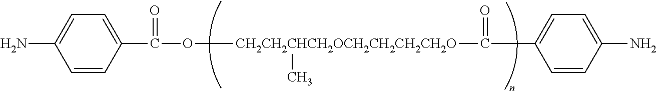
the active hydrogen equivalent of the flexible amine hardener should be controlled between 100-500 g/eq;
the amount of the flexible amine hardener, based on the ratio between amine hydrogen equivalent and epoxy resin epoxy equivalent, is 5-30%; the amount of the ester compounds, based on the ratio between ester equivalent and epoxy resin epoxy equivalent, is 70-95%.

2. The epoxy resin composition of claim 1, wherein the epoxy resin having two or more epoxy groups in one molecular epoxy resin, comprising at least one of bisphenol A epoxy resins, bisphenol F epoxy resin, biphenyl epoxy resins, o-cresol t epoxy resin, naphthol novolac epoxy resin and dicyclopentadiene epoxy resin.

3. The epoxy resin composition of claim 1, wherein the ester compound is one or more ester compounds as follows: 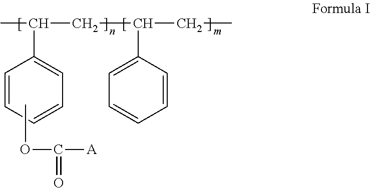
wherein A is a substituted or unsubstituted phenyl group, a substituted or unsubstituted naphthyl group, C1-C8 alkyl group, m and n is natural numbers, m/n=0.8-19; 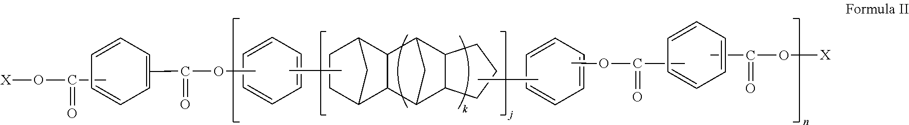
wherein X is benzene ring or naphthalene ring, j is 0 or 1, k is 0 or 1, and n represents that the average repeating unit is 0.25-1.25;
preferably, the eater compound is that of formula I.

4. The epoxy resin composition of claim 1, further comprising a curing accelerator, the curing accelerator is one or a mixture of imidazole compounds and derivatives thereof, piperidine compounds, Lewis acids and triphenylphosphine.

5. The epoxy resin composition of claim 1, further comprising components as follows: organic or inorganic filler; The mixed amount of the filler, relative to the total 100 parts by weight of the epoxy resin, the flexible amine hardener and the ester compound, is 5-1000 parts by weight.

6. The epoxy resin composition of claim 5, wherein the inorganic filler is one or more selected from crystalline silica, fused silica, spherical silica, hollow silica, glass powder, aluminum nitride, boron nitride, silicon carbide, aluminum hydroxide, titanium dioxide, strontium titanate, barium titanate, aluminum oxide, barium sulfate, talcum powder, calcium silicate, calcium carbonate, and mica.

7. The epoxy resin composition of claim 5, wherein the organic filler is one or more selected from polytetrafluoroethylene powder, polyphenylene sulfide, and polyether sulfone powder.

8. The epoxy resin composition of claim 1, further comprising a flame retardant, the flame retardant may be a bromine-containing or a halogen-free flame retardant, a halogen flame retardant, a phosphorus-containing flame retardants, a silicon-containing flame retardant, a nitrogen-containing flame retardants; the amount of the flame retardant, relative to the total 100 parts by weight of the epoxy resin, the flexible amine hardener and the ester compound, is 5-100 parts by weight, and preferred to be 10-50 parts by weight.

9. A prepreg prepared by using the epoxy resin composition of any of claim 1, which comprises a reinforce material and the epoxy resin composition attached thereon after being impregnated and dried.

10. A laminate prepared by using the prepreg of claim 9, which comprises as least one piece of the prepreg of claim 9.
